(19) United States
(12) Patent Application Publication
(10) Pub. No.: US 2009/0008764 A1
(43) Pub. Date: Jan. 8, 2009

(54) Ultra-Thin Wafer-Level Contact Grid Array

(76) Inventors: Hsin-Hui Lee, Kaohsiung (TW); Mirng-Li Lii, Sinpu Township (TW)

Correspondence Address: SLATER & MATSIL, L.L.P., 17950 PRESTON ROAD, SUITE 1000, DALLAS, TX, 75252, US

(21) Appl. No.: 11/772,321

(22) Filed: Jul. 2, 2007

(51) Int. Cl. H01L 23/488

(52) U.S. Cl. 257/690; 257/737; 257/E23.023

(57) ABSTRACT

Wafer-level chip-scaled packaging (WLCSP) features are described in a semiconductor die having a plurality of lands providing electrical connection between a surface of the semiconductor die and an active layer of the semiconductor die. Each of the plurality of lands rises above the surface no more than 10 μm. The device also has a plurality of solder bars at corners of the semiconductor die, the plurality of solder bars also rising above the surface no more than 10 μm. The solder bars add overall contiguous surface area to the solder joints between the die package and its final attachment.

### TECHNICAL FIELD

The present invention relates generally to wafer level chip scale packaging (WLCSP), and more particularly to an ultra-thin contact grid array used in WLCSP.

### BACKGROUND

The past few decades have seen many shifts in electronics and semiconductor packaging that have impacted the entire semiconductor industry. The introduction of surface-mount technology (SMT), ball grid array (BGA) and land grid array (LGA) packages were generally important steps for high-throughput assembly of a wide variety of integrated circuit (IC) devices, while, at the same time, allowing reduction of the pad pitch on the printed circuit board. Conventionally packaged ICs have a structure basically interconnected by fine gold wire between metal pads on the die and electrodes spreading out of molded resin packages. Dual Inline Package (DIP) or Quad Flat Package (QFP) are fundamental structures of current IC packaging. However, increased pin count peripherally designed and arranged around the package typically results in too short of a pitch of lead wire, yielding limitations in board mounting of the packaged chip.

Chip-scale or chip-size packaging (CSP), BGA, and LGA are just some of the solutions that enable dense electrode arrangement without greatly increasing the package size. CSP provides for wafer packaging on a chip-size scale. CSP typically results in packages within 1.2 times the die size, which greatly reduces the potential size of devices made with the CSP material. Although these advances have allowed for miniaturization in electronic devices, the ever-demanding trend toward even smaller, lighter, and thinner consumer products have prompted even further attempts at package miniaturization.

To fulfill market demands toward increased miniaturization and functionality, WLCSP has been introduced in recent years for generally increasing density, performance, and cost-effectiveness, while decreasing the weight and size of the devices in the electronic packaging industry. In WLCSP, the packaging is typically generated directly on the die with contacts provided by BGA or LGA. Recent advanced electronic devices, such as mobile phones, mobile computers, camcorders, personal digital assistants (PDAs), and the like, utilize compact, light, thin, and very densely packaged ICs. Using WLCSP for packaging smaller die size devices with lower numbers of pins, corresponding to larger number of chips on one wafer, is, therefore, usually advantageous and cost-effective. However, the second level connectors, i.e., the connectors between the semiconductor package and the printed circuit board (PCB), remain relatively high—between 0.2 and 0.3 mm.

One disadvantage of current WLCSP contact technology is that, as the package size and die size have gotten smaller and smaller, the connector height has remained the same. FIG. 1 is a cross-sectional view of die package 10. Die package 10 comprises semiconductor device 100 and solder ball 101 placed on top of under bump metallurgy (UBM) layer 102 deposited onto die package 10 to facilitate the placement. Solder ball 101 is shown at a typical package height of between 0.2 and 0.3 mm. Regardless of how small die package 10 may be manufactured, solder ball 101 height remains between 0.2 and 0.3 mm high.

A second disadvantage of current WLCSP contact technology is the strains that occur within the solder ball arrays. In a conventional leaded package, strains are relieved through the compliant gull wing leads. In area-array solder ball packages the strain is typically experienced in the solder joint. The constant strain often leads to solder joint failure during the package lifecycle. The important mechanical variables connected to the strain/reliability of WLCSP technology are: (a) ball distance from neutral point (DNP), which is determined by chip-size and bump pitch; (b) the bump standoff; and (c) the number of bumps. The greater the DNP (i.e., the further the bump is from the neutral point), the greater the strain generated in the solder bump and on the underlying surface. Thus, the solder bumps, which are the furthest from the neutral point of the die, may experience the highest solder joint failure. Current methodologies to reduce or relieve strain in area-array contact packages involve maintaining larger solder balls or depositing a layer of material encasing the bumps which exhibit a coefficient of thermal expansion (CTE) similar to that of the underlying packaging. The better matched CTEs reduce the strains on the solder joint. However, the addition of the encasing layer adds material and processing steps to the die fabrication.

### SUMMARY OF THE INVENTION

These and other problems are generally solved or circumvented, and technical advantages are generally achieved, by preferred embodiments of the present invention that provide an array of low-height lands or connectors, each rising 10 μm or less above the surface of the die package. In order to compensate for the reliability issues experienced in such WLCSP features, a series of solder bars or corner bars are placed at the corners of the die. These solder bars provide additional contiguous surface area for the solder joints at the point on the die furthest from the neutral point, thus, enhancing the overall reliability of the die attachment.

In accordance with a preferred embodiment of the present invention, a semiconductor device includes a semiconductor die having a plurality of lands providing electrical connection between a printed circuit board (PCB) and the semiconductor die, wherein each of the plurality of lands rises above a surface of the semiconductor die no more than 10 μm. The device also has a plurality of solder bars at corners of the semiconductor die, the plurality of solder bars also rising above the surface no more than 10 μm.

In accordance with another preferred embodiment of the present invention, an ultra-thin die package includes a plurality of lands on a connecting surface of the ultra-thin die package, wherein each of the lands extends above the connecting surface less than or equal to 10 μm. The die package also includes a corner bar at each corner of the ultra-thin die package, wherein each corner bar has a surface area greater than one of the plurality of lands and extends above the connecting surface a distance about equal to the plurality of lands.

In accordance with another preferred embodiment of the present invention, a semiconductor die package includes a multi-layer die with an array of connectors extending from a surface of the multilayer die, wherein each of the connectors in the array extends less than or equal to 10 μm above the surface. A plurality of solder bars is located at each corner of the semiconductor die package, wherein the plurality of solder bars extends from the surface a height about equal to each of the connectors.

An advantage of a preferred embodiment of the present invention is that it provides an ultra-thin package height for semiconductor devices.

A further advantage of a preferred embodiment of the present invention is that the additional solder bars at the corners of the die enhance the reliability of the solder joints.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of a typical die package;

FIG. 2 is a cross-sectional view of a WLCSP feature configured according to one embodiment of the present invention;

FIG. 3 is a cross-sectional view of a WLCSP feature configured according to one embodiment of the present invention;

FIG. 4A is a planar view of a die package using WLCSP features configured according to one embodiment of the present invention;

FIG. 4B is a cross-sectional view of a die package using WLCSP features configured according to one embodiment of the present invention; and

FIG. 5 is a planar view of a die package using WLCSP features configured according to one embodiment of the present invention.

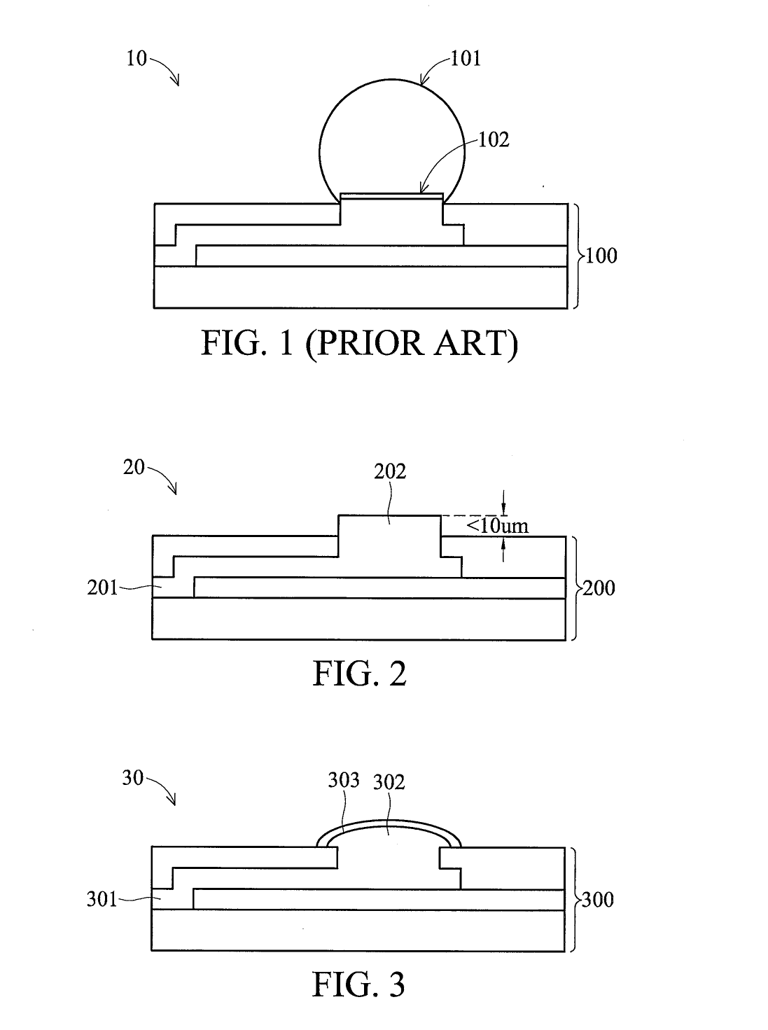

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

With reference now to FIG. 2, there is shown a cross-sectional view of WLCSP feature 20 configured according to one embodiment of the present invention. WLCSP feature 20 comprises low-height land 202 fashioned on die package 200. Die package 200 is a typical die having multiple layers of semiconductor material including redistribution layer 201 which provides connection between low-height land 202 and the active portion of die package 200. Low-height land 202 connects to a PCB (not shown) in which a full electrical connection runs from the PCB to the active portion of die package 200.

In a preferred embodiment of the present invention, low-height land 202 stands at 10 μm above the surface of die package 200. It should be noted that in additional and/or alternative embodiments of the present invention, low-height land 202 may stand at a height less than 10 μm, while still standing above the surface of die package 200.

It should be noted that the embodiment of the present invention described and illustrated in FIG. 2 shows only a single array connector/land. A single connector is shown merely for clarity. In practice, a typical die package may have tens or hundreds of array connectors configured according to the various embodiments of the present invention. Thus, while the figures herein may illustrate only one or a few array connectors, this is purely for clarity of explanation and is not intended to limit the present invention to a specific number of lands or connectors.

FIG. 3 is a cross-sectional view of WLCSP feature 30 configured according to one embodiment of the present invention. WLCSP feature 30 comprises low-height land 302 provided on die package 300. Die package 300 includes multiple semiconductor layers including redistribution layer 301. In the embodiment of WLCSP feature 30 depicted in FIG. 3, low-height land 302 has a mushroom shape which includes a piece that extends on top of die package 300. Additionally, enhancement film 303 is deposited on top of low-height land 302 in order to enhance the solderability and reliability of WLCSP feature 30.

It should be noted that in a preferred embodiment of the present invention, the materials used in providing the conducting connectors and redistribution layers are made without the use of lead (Pb). The use of lead-free materials preferably creates a more environmentally compatible device. Examples of lead-free materials that may be used for enhancement film 303 are gold, palladium, gold-palladium alloy, or the like.

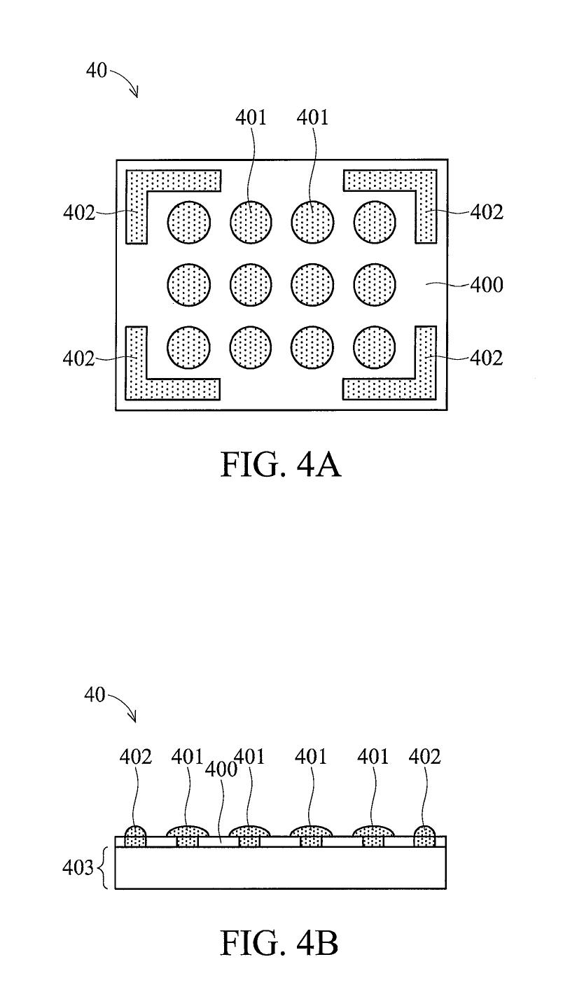

FIG. 4A is a planar view of die package 40 using WLCSP features configured according to one embodiment of the present invention. Die package 40 includes low-height lands 401 deposited in an area array on die surface 400. The DNP in WLCSP technology leads to lower reliability in the solder joints of the typical solder bump or solder ball. When the height of the bump is decreased as described herein, the stresses and strains that naturally occur within the solder joints are not distributed over a smaller structure. However, in order to enhance the solder joint reliability, corner bars 402 are placed at the corners of die package 40. The increased area covered by corner bars 402, which reside at the largest DNP on die package 40, enhance the entire solder joint reliability of die package 40.

FIG. 4B is a cross-sectional view of die package 40 using WLCSP features configured according to one embodiment of the present invention. Corner bars 402 stand at about the same height as low-height lands 401 and are fashioned within die surface 400 of die 403. When die package 40 is, thereafter, attached to an end location, the solder joint area is not limited to only the joints occurring at low-height lands 401, but also includes the larger contiguous area of corner bars 402. This increased solder joint area increases and enhances the overall reliability of the die package 40 connection.

It should be noted that in additional and/or alternative embodiments of the present invention, the solder bars, such as corner bars 402, may have the cross-sectional shape of a mushroom, as depicted in FIG. 4B, or may be simple posts or pillars. It should further be noted that, while corner bars 402 are shown as ‘L’-shaped, other shapes may be beneficially used to enhance the solderability and reliability of the die package. Additionally, additional and/or alternative embodiments of the present invention may deposit a solder enhancement film, such as enhancement film 303 (FIG. 3), on top of corner bars 402 to enhance the solderability and reliability of that feature.

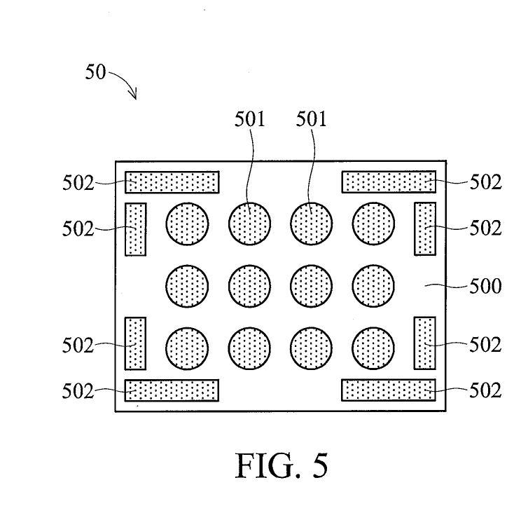

FIG. 5 is a planar view of ultra-thin die package 50 using WLCSP features configured according to one embodiment of the present invention. The embodiment illustrated in FIG. 5 enhances the solder joint reliability by adding solder bars 502 to the corners of die package 50. The increased area covered by corner bars 502, which reside at the greatest DNP on die wafer 500, enhance the entire solder joint reliability of solder lands 501.

Although the present invention and its advantages have been described in detail, it should be understood that various changes, substitutions and alterations can be made herein without departing from the spirit and scope of the invention as defined by the appended claims. For example, many of the features and functions discussed above can be implemented using various materials.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a semiconductor die;
a plurality of lands providing electrical connection between a printed circuit board and said semiconductor die, wherein each of said plurality of lands rises above a surface of said semiconductor die no more than 10 μm; and
a plurality of solder bars at corners of said semiconductor die, said plurality of solder bars rising above said surface no more than 10 μm.

2. The semiconductor device of claim 1 wherein each of said plurality of lands and said plurality of solder bars has a cross-sectional shape of one of:
a mushroom; and
a pillar.

3. The semiconductor device of claim 1 further comprising:
a solder-enhancement film layered over said plurality of lands and said plurality of solder bars.

4. The semiconductor device of claim 3 wherein said solder-enhancement film is made from a material selected from the group consisting essentially of:
gold;
palladium; and
a gold-palladium alloy.

5. The semiconductor device of claim 1 wherein said semiconductor device is manufactured and attached to a final location using lead-free material.

6. The semiconductor device of claim 1 further comprising:
a redistribution layer providing a connection between said plurality of lands and said semiconductor die.

7. The semiconductor device of claim 1 wherein each of said plurality of solder bars has a planar-view shape of one of:
an ‘L’;
a rectangle; and
a geometric shape having a general length greater than its general width.

8. An ultra-thin die package comprising:
a plurality of lands on a connecting surface of said ultra-thin die package, wherein each of said plurality of lands extends above said connecting surface less than or equal to 10 μm; and
a corner bar at each corner of said ultra-thin die package, wherein each said corner bar has a surface area greater than one of said plurality of lands and extends above said connecting surface a distance about equal to said plurality of lands.

9. The ultra-thin die package of claim 8 further comprising:
an enhancement film deposited over each of said plurality of lands and each said corner bar.

10. The ultra-thin die package of claim 9 wherein said enhancement film is selected from the group consisting essentially of:
gold;
palladium; and
gold-palladium alloy.

11. The ultra-thin die package of claim 8 wherein said plurality of lands and each said corner bar comprise lead-free material.

12. The ultra-thin die package of claim 8 wherein said plurality of lands and each said corner bar has a cross-sectional shape of one of:
a mushroom; and
a pillar.

13. The ultra-thin die package of claim 8 wherein each said corner bar has a planar-view general shape of one of:
an ‘L’;
a rectangle; and
a geometric shape having a general length greater than its general width.

14. A semiconductor die package comprising:
a multi-layer die;
an array of connectors extending from a surface of said multi-layer die, wherein each of said connectors in said array extends less than or equal to 10 μm above said surface; and
a plurality of solder bars at each corner of said semiconductor die package, wherein said plurality of solder bars extends from said surface a height about equal to each of said connectors.

15. The semiconductor die package of claim 14 further comprising:
a solder-enhancement film on said array of connectors and said plurality of solder bars, wherein said solder-enhancement film is lead-free.

16. The semiconductor die package of claim 14 wherein each of said connectors in said array and each of said plurality of solder bars has a cross-sectional shape comprising one of:
a mushroom; and
a post.

17. The semiconductor die package of claim 14 wherein each of said plurality of solder bars has a planar-view shape generally comprising one of:
an ‘L’;
a rectangle; and
a geometric shape having a general length greater than its general width.
